(19) United States
(12) Patent Application Publication
(10) Pub. No.: US 2026/0064173 A1
(43) Pub. Date: Mar. 5, 2026

(54) THERMAL REPORTING DRIVER FOR PROVIDING ACTIVE COOLING IN PRE AND POST BOOT ENVIRONMENTS

(71) Applicant: Dell Products L.P., Round Rock, TX (US)

(72) Inventors: SURAJ M. VARMA, Portland, OR (US); ADOLFO SANDOR MONTERO, Pflugerville, TX (US); ALOK PANT, Austin, TX (US)

(21) Appl. No.: 18/820,611

(22) Filed: Aug. 30, 2024

(51) Int. Cl. G06F 1/20; H05K 7/20

(52) U.S. Cl. CPC G06F 1/206; H05K 7/20172; H05K 7/20209

(57) ABSTRACT

Methods and systems for managing cooling of a data processing system. In particular, active cooling using a fan controlled by an embedded controller is provided in a data processing system having components from a thermal architecture that is only capable of providing passive cooling through throttling of a motherboard of the data processing system. The thermal architecture is based on a passive cooling thermal architecture of a computing device without the capacity to include the fan and the embedded controller, and the motherboard is one of the components of the thermal architecture.

### FIELD

Embodiments disclosed herein relate generally to managing data processing systems. More particularly, embodiments disclosed herein relate to systems and methods for managing cooling of data processing systems.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components and the components of other devices may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1 shows a block diagram illustrating a distributed system in accordance with one or more embodiments.

FIG. 2A shows a block diagram illustrating an example data processing system in accordance with one or more embodiments.

FIG. 2B shows a block diagram illustrating another example of a data processing system in accordance with an embodiment.

FIG. 3 shows a data flow diagram in accordance with one or more embodiments.

FIG. 4 shows a flowchart in accordance with one or more embodiments.

FIG. 5 shows a block diagram illustrating a data processing system in accordance with one or more embodiments.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing cooling of a data processing system. For example, data processing system may be cooled passively using passive cooling techniques (e.g., through throttling of the central processing unit (CPU), application management, or the like where a physical fan is not involved in the cooling process) or may be cooled actively using active cooling techniques (e.g., using one or more physical fans installed within the data processing system).

However, certain thermal architectures (e.g., the combination of hardware and/or software components within a data processing system that provide thermal management including the cooling of the data processing system) are designed to be capable of providing only one of the two cooling techniques (e.g., active and passive cooling techniques). For example, data processing systems such as mobile phones, tablets, or the like have housings (e.g., casings, chassis, bodies, or the like) that are not designed to accommodate fans (e.g., housing that do not have the space/capacity to house a physical fan). Without having fans, the thermal architectures in such devices are designed to be capable of providing only passive cooling techniques.

Furthermore, the thermal architectures in such devices are designed to be able to provide passive cooling only after an operating system (OS) of these devices has fully booted up (namely, an OS-based driver is required to pull temperatures from components of these devices before the device is able to determine whether any cooling is even needed). In other words, during a pre-boot process when the OS is being started up (e.g., when the OS is not yet available to instantiate and control the OS-based driver), such thermal architectures have no capability of providing cooling for the data processing systems in which they are hosted.

Even further, when components (namely, the CPUs) from such thermal architectures that are only capable of providing passive cooling are incorporated into a different environment where components (e.g., embedded controllers, fans, or the like) that provide active cooling techniques are available, these components are not capable of communicating with one another to provide the active cooling techniques. Namely, no mechanisms (e.g., firmware, software, or hardware mechanisms) currently exist for such embedded controllers to communicate and retrieve thermal information from such CPUs.

Further, certain data processing systems may require wattages above approximately 10 Watts to operate. In such data processing systems, it is not possible to cool the data processing system using only passive cooling techniques. In particular, so much throttling (e.g., of the CPU) would be required that the data processing system becomes completely unusable. However, because the components in these thermal architectures that are only able to provide passive cooling were not originally designed to be compatible with components from thermal architectures having active cooling capabilities, it is difficult to expand such systems with thermal architectures that are only able to provide passive cooling to operate at above approximately 10 Watts.

To address the limitations of data processing systems with such hybrid thermal architectures (e.g., a hybrid thermal architecture with a CPU adapted from a first thermal architecture that are only capable of providing passive cooling and embedded controllers and fans adapted from a second thermal architecture that is capable of providing active cooling), where components adapted from the different thermal architectures were not originally designed to be able to communicate with one another, embodiments disclosed herein provide mechanisms (e.g., techniques and components) that allow these components to work together to be able to provide both passive and active cooling for such data processing systems during and after a pre-boot stage of these data processing systems.

In particular, embodiments disclosed herein provide new thermal drivers that are able to assist an embedded controller (that is able to control a fan to provide active cooling techniques) to retrieve thermal information from the CPU adapted from the thermal architecture that is only capable of providing passive cooling, which was not originally designed to work with the embedded controller to provide active cooling techniques. Such thermal information may be retrieved without using platform environment control interface (PECI) tunneling through an enhanced serial peripheral interface (eSPI) interface that the embedded controller traditionally uses to retrieve such thermal information from a CPU originally designed to work with the embedded controller to provide active cooling techniques.

The new thermal drivers of embodiments disclosed herein also allow thermal information to be retrieved from the CPU before an OS hosted on the CPU has completely booted up. Said another way, thermal information originally not available until an OS-based driver is running is now available to be retrieved and provided to the embedded controller during a pre-boot stage of the data processing system.

By enabling these originally incompatible components from different thermal architectures to work together, embodiments disclosed herein advantageously not only prevents the need for existing CPUs (namely, existing CPUs adapted from a thermal architecture that is only capable of providing passive cooling) to be completely redesigned to be able to also provide active cooling techniques but also allows more versatile use of such existing CPUs in systems that were once deems incompatible with such existing CPUs.

Furthermore, by providing better and more versatile thermal management techniques through making active cooling techniques available during and after the pre-boot stage, embodiments disclosed herein also improve not only the operations of such data processing systems (having such hybrid thermal architectures) but also the computer functionalities (e.g., preventing overheating during pre-boot or the like) of such data processing systems.

In an embodiment, a computer-implemented method for providing active cooling using a fan controlled by an embedded controller in a data processing system with an existing thermal architecture that is only capable of providing passive cooling through throttling of a motherboard of the data processing system is provided. The method may include: obtaining, by a first thermal driver of the data processing system, system temperature of the data processing system, the first thermal driver being incapable of communicating with the embedded controller; obtaining, by a second thermal driver of the data processing system, the system temperature from the first thermal driver; providing, by the second thermal driver, the system temperature to the embedded controller via an inter-integrated circuit (I2C)/improved inter-integrated circuit (I3C) interface; and providing, by the embedded controller, active cooling for the data processing system by controlling the fan based on the system temperature, the embedded controller being incapable of obtaining the system temperature without aid from the second thermal driver.

When the method is performed during a startup process of the data processing system before an operating system (OS) has completed booting up, the first thermal driver is a first Driver Execution Environment (DXE) driver that obtains the system temperature directly from a motherboard installed within the data processing system, and the second thermal driver is a second DXE driver that obtains the system temperature from the first DXE driver using a Unified Extensible Firmware Interface (UEFI) Timer Event mechanism.

The second DXE driver obtains the system temperature from the first DXE driver by retrieving the system temperature from the first DXE driver using the UEFI Timer Event mechanism.

The second DXE driver provides the system temperature to the embedded controller using a Multi-Channel Inter-Processor Mailbox (MBOX) I2C/I3C communication protocol.

When the method is performed after completion of a startup process of the data processing system when the OS of the data processing system is running, the first thermal driver is high-level operating system (HLOS) thermal driver that obtains the system temperature directly from the motherboard, and the second thermal driver is an Advanced Configuration and Power Interface Source Language (ASL) based driver.

The second thermal driver provides the system temperature to the embedded controller using an ASL-I2C/I3C communication protocol.

The method may further include: determining, during the startup process and while the embedded controller provides the active cooling using the fan, that the system temperature is still above a predetermined threshold; and causing, by the embedded controller and in response to the determination, throttling of the motherboard to also provide the passive cooling in addition to providing the active cooling using the fan.

The thermal architecture is based on a passive cooling thermal architecture of a computing device without a capacity to include the fan and the embedded controller, and the motherboard is one of the components of the thermal architecture.

A non-transitory media may include instructions that when executed by a processor cause the computer-implemented method to be performed.

The data processing system may include the non-transitory media and a processor, and may perform the computer-implemented method when the computer instructions are executed by the processor.

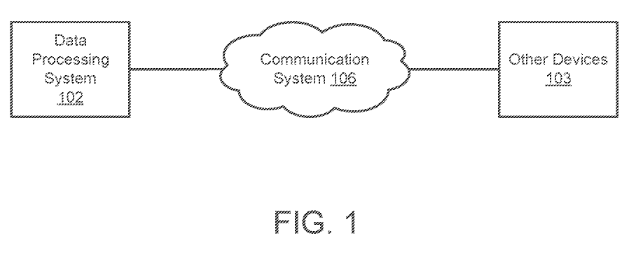

Turning to FIG. 1, a block diagram illustrating a distributed system in accordance with an embodiment is shown. The (distributed) system shown in FIG. 1 may provide computer-implemented services. The computer-implemented services may include any type and quantity of services including, for example data services (e.g., data storage, access and/or control services), communication services (e.g., instant messaging services, video-conferencing services), and/or any other type of service that may be implemented with a computing device.

The computer-implemented services may be provided by one or more components of the system of FIG. 1. For example, data processing system 102 may be implemented as any type of computing device (e.g., desktop computers, mobile phones, tablets, laptops, or the like) that may provide computer-implemented services. For example, the computer-implemented services may include data storage services, instant messaging services, database services, and/or any other type of service that may be implemented with a computing device.

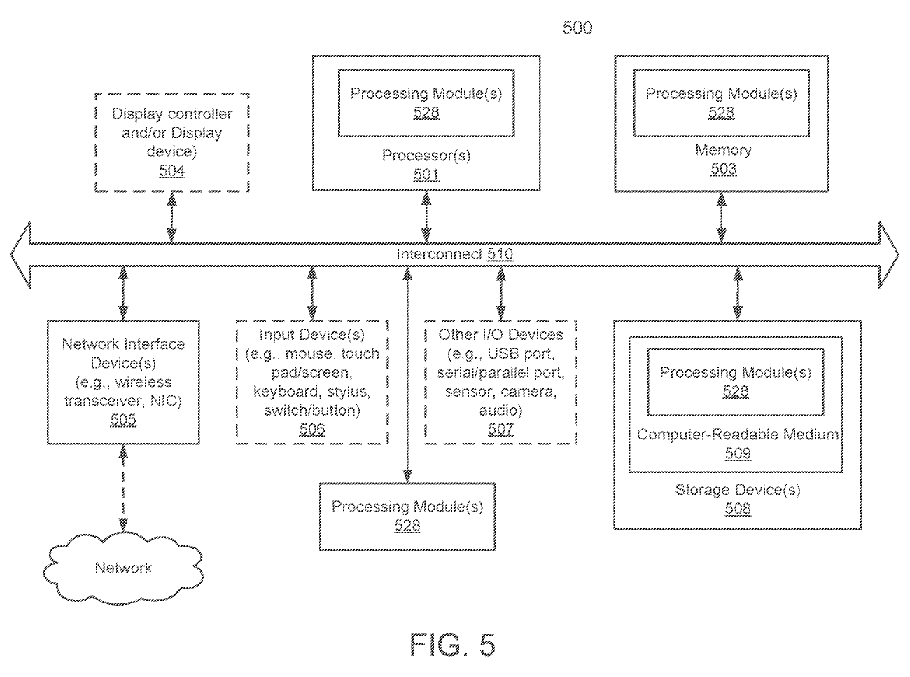

Such computer-implemented services may be provided to one or more users of the data processing system 102 and/or to users of other devices 103 (e.g., via the users of other devices 103 requesting such computer-implemented services from the data processing system 102). Conversely, the other devices 103 may also provide computer-implemented services to the data processing system 102. In embodiments, any of the data processing system 102 and the other devices 103 may implemented as a computing device (e.g., computing device of FIG. 5)

To provide the computer-implemented services, the system of FIG. 1 may include any number of the data processing system 102 and the other devices 103. Data processing system 102 and the other devices 103 may provide the computer-implemented services to their respective users and/or to other devices (not shown). Data processing system 102 and the other devices 103 may provide similar and/or different computer-implemented services. Data processing system 102 and the other devices 103 may also be organized in one or more deployments (e.g., server farms, remote storage environments, Cloud-RAN deployments, or the like) to collectively provide the computer-implemented services.

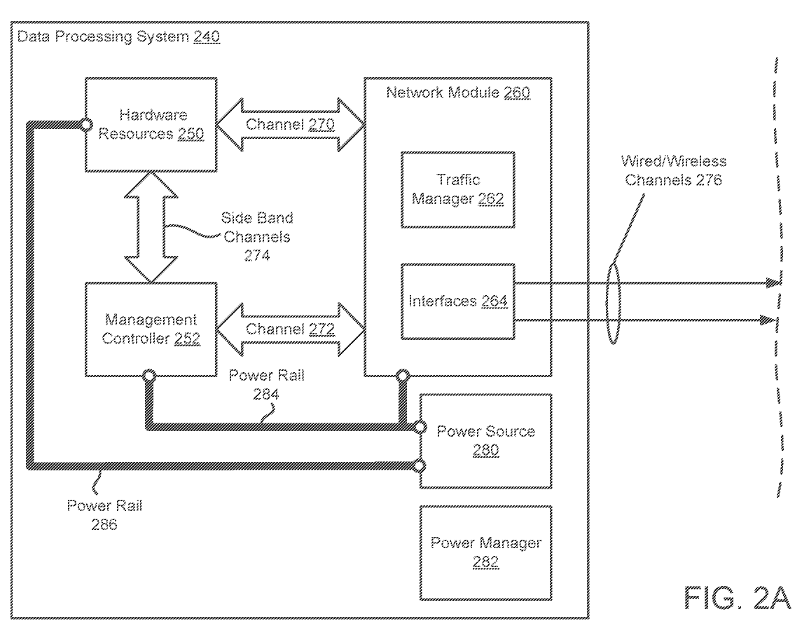

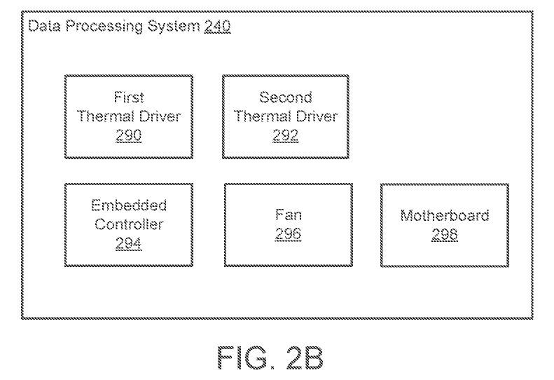

To provide the computer-implemented services, data processing systems 102A-102N may include various hardware components (e.g., processors, memory modules, storage devices, peripheral devices, etc.) and host various software components (e.g., operating systems, application, startup managers such as basic input-output systems, etc.). These hardware and software components (discussed in more detail below in FIG. 2A) may provide the computer-implemented services via their operation.

The software components may be implemented using various types of services. For example, each data processing system of the data processing systems 102A-102N may host various services that provide the computer-implemented service (e.g., application services) and/or that manage the operation of these services (e.g., management services). The aggregate (e.g., combination) of the management and application services may be a complete service that provide desired functionalities.

Any of the components illustrated in FIG. 1 may be operably connected to each other (and/or components not illustrated) with communication system 106. In an embodiment, communication system 106 includes one or more networks that facilitate communication between any number of components. The networks may include wired networks and/or wireless networks (e.g., and/or the Internet). The networks may operate in accordance with any number and/or types of communication protocols (e.g., such as the internet protocol).

While illustrated in FIG. 1 as including a limited number of specific components, a system in accordance with an embodiment may include fewer, additional, and/or different components than those illustrated therein.

Turning to FIG. 2A, a diagram illustrating an example data processing system 240 in accordance with an embodiment is shown. The data processing system 240 shown in FIG. 2A may be similar to data processing system 102 shown in FIG. 1.

To provide computer-implemented services, data processing system 240 may include any quantity of hardware resources 250. Hardware resources 250 may be in-band hardware components, and may include a processor (e.g., as part of a motherboard of the data processing system 240) operably coupled to memory, storage, and/or other hardware components.

In embodiments, the hardware resources 250 may also include an embedded controller. The embedded controller may be implemented as a microcontroller with separate memory (e.g., random access memory (RAM)) from the processor. The embedded controller may also operate independently from the processor and perform independent functions such as, but not limited to: (i) receiving and processing signals from a keyboard or other input devices of the data processing system 240; (ii) retrieving thermal measurements (e.g., thermal information) from various components of the data processing system (e.g., from the CPU, from the motherboard, from one or more graphical processing units (GPUs), from one or more thermal sensors installed within the data processing system 240, or the like); (iii) using the thermal measurements to control one or more fans installed within the data processing system 240 and/or to throttle the CPU and/or GPUs; or the like.

In embodiments, the processor may host various management entities such as operating systems (OS), drivers (e.g., OS-based and non-OS based drivers), network stacks, and/or other software entities that provide various management functionalities. For example, the OS and drivers may provide abstracted access to various hardware resources. Likewise, the network stack may facilitate packaging, transmission, routing, and/or other functions with respect to exchanging data with other devices.

For example, the network stack may support transmission control protocol/internet protocol communication (TCP/IP) (e.g., the Internet protocol suite) thereby allowing the hardware resources 250 to communicate with other devices via packet switched networks and/or other types of communication networks.

The processor may also host various applications that provide the computer-implemented services. The applications may utilize various services provided by the management entities and use (at least indirectly) the network stack to communicate with other entities.

However, use of the network stack and the services provided by the management entities may place the applications at risk of indirect compromise. For example, if any of these entities trusted by the applications are compromised, then these entities may subsequently compromise the operation of the applications. For example, if various drivers and/or the communication stack are compromised, then communications to/from other devices may be compromised. If the applications trust these communications, then the applications may also be compromised.

For example, to communicate with other entities, an application may generate and send communications to a network stack and/or driver, which may subsequently transmit a packaged form of the communication via channel 270 to a communication component, which may then send the packaged communication (in a yet further packaged form, in some embodiments, with various layers of encapsulation being added depending on the network environment outside of data processing system 240) to another device via any number of intermediate networks (e.g., via wired/wireless channels 276 that are part of the networks).

To reduce the likelihood of the applications and/or other in-band entities from being indirectly compromised, data processing system 240 may include management controller 252 and network module 260. Each of these components of data processing system 240 is discussed below.

Management controller 252 may be implemented, for example, using a system on a chip or other type of independently operating computing device (e.g., a microcontroller or the like that is independent from the in-band components, such as hardware resources 250 of a host data processing system 240). Management controller 252 may provide various management functionalities for data processing system 240. For example, management controller 252 may monitor various ongoing processes performed by the in-band components, may manage power distribution, thermal management, and/or may perform other functions for managing data processing system 240. In some embodiments, the management controller 252 may act as the embedded controller of the data processing system 240. In some embodiments, the management controller 252 may be the sole embedded controller of the data processing system 240 (e.g., there is no separate embedded controller as part of the hardware resources 250).

To provide its functionalities, management controller 252 may be operably connected to various components via sideband channels 274 (in FIG. 2A, a limited number of sideband channels are included for illustrative purposes, it will be appreciated that management controller 252 may communicate with other components via any number of sideband channels). The sideband channels may be implemented using separate physical channels, and/or with a logical channel overlay over existing physical channels (e.g., logical division of in-band channels). The sideband channels may allow management controller 252 to interface with other components and implement various management functionalities such as, for example, general data retrieval (e.g., to snoop ongoing processes), telemetry data retrieval (e.g., to identify a health condition/other state of another component), function activation (e.g., sending instructions that cause the receiving component to perform various actions such as displaying data, adding data to memory, causing various processes to be performed), and/or other types of management functionalities.

For example, to reduce the likelihood of indirect compromise of an application hosted by hardware resources 250, management controller 252 may enable information from other devices to be provided to the application without traversing the network stack and/or management entities of hardware resources 250. To do so, the other devices may direct communications including the information to management controller 252.

Management controller 252 may then, for example, send the information via sideband channels 274 to hardware resources 250 (e.g., to store it in a memory location accessible by the application, such as a shared memory location, a mailbox architecture, or other type of memory-based communication system) to provide it to the application. Thus, the application may receive and act on the information without the information passing through potentially compromised entities. Consequently, the information may be less likely to also be compromised, thereby reducing the possibility of the application becoming indirectly compromised. Similarly, processes may be used to facilitate outbound communications from the applications.

Management controller 252 may be operably connected to communication components of data processing system 240 via separate channels (e.g., 272) from the in-band components, and may implement or otherwise utilize a distinct and independent network stack (e.g., TCP/IP). Consequently, management controller 252 may communicate with other devices independently of any of the in-band components (e.g., does not rely on any hosted software, hardware components, etc.). Accordingly, compromise of any of hardware resources 250 and hosted components may not result in indirect compromise of any management controller 252, and entities hosted by management controller 252.

To facilitate communication with other devices, data processing system 240 may include network module 260. Network module 260 may provide communication services for in-band components and out-of-band components (e.g., management controller 252) of data processing system. To do so, network module 260 may include traffic manager 262 and interfaces 264.

Traffic manager 262 may include functionality to (i) discriminate traffic directed to various network endpoints advertised by data processing system 240, and (ii) forward the traffic to/from the entities associated with the different network endpoints. For example, to facilitate communications with other devices, network module 260 may advertise different network endpoints (e.g., different media access control address/internet protocol addresses) for the in-band components and out-of-band components. Thus, other entities may address communications to these different network endpoints. When such communications are received by network module 260, traffic manager 262 may discriminate and direct the communications accordingly (e.g., over channel 270 or channel 272, in the example shown in FIG. 2A, it will be appreciated that network module 260 may discriminate traffic directed to any number of data units and direct it accordingly over any number of channels).

Accordingly, traffic directed to management controller 252 may never flow through any of the in-band components. Likewise, outbound traffic from the out-of-band component may never flow through the in-band components.

Thus, if in-band components of data processing system 240 are unsecured and/or compromised (e.g., by a malicious party), then the computing instructions sent using out-of-band components and via out-of-band communication channels may be less likely to be intercepted and/or modified (e.g., by the malicious party), and the operation of data processing system 240 may be more likely to be updated according to its reported location.

To support inbound and outbound traffic, network module 260 may include any number of interfaces 264. Interfaces 264 may be implemented using any number and type of communication devices which may each provide wired and/or wireless communication functionality. For example, interfaces 264 may include a wireless wide area network (WWAN) card, a Wi-Fi card, a wireless local area network card, a wired local area network card, an optical communication card, and/or other types of communication components. These components may support any number of wired/wireless channels 276.

Thus, from the perspective of an external device, the in-band components and out-of-band components of data processing system 240 may appear to be two independent network entities, that may be independently addressable and/or otherwise unrelated to one another.

To facilitate management of data processing system 240 over time, hardware resources 250, management controller 252 and/or network module 260 may be positioned in separately controllable power domains. By being positioned in these separate power domains, different subsets of these components may remain powered while other subsets are unpowered.

For example, management controller 252 and network module 260 may remain powered while hardware resources 250 is unpowered. Consequently, management controller 252 may remain able to communicate with other devices even while hardware resources 250 are inactive. Similarly, management controller 252 may perform various actions while hardware resources 250 are not powered and/or are otherwise inoperable, unable to cooperatively perform various process, are compromised, and/or are unavailable for other reasons. Therefore, if hardware resources 250 become unavailable (e.g., due to being unpowered), then out-of-band components may remain powered, allowing network module 260 to continue to generate location data for data processing system 240.

To implement the separate power domains, data processing system 240 may include a power source (e.g., 280) that separately supplies power to power rails (e.g., power rail 284, power rail 286) that power the respective power domains. Power from the power source (e.g., a power supply, battery, etc.) may be selectively provided to the separate power rails to selectively power the different power domains. A power manager (e.g., 282) that may manage power from power source 280 may be supplied to the power rails. Management controller 252 may cooperate with power manager 282 to manage supply of power to these power domains.

In FIG. 2A, an example implementation of separate power domains using power rails 284-286 is shown. The power rails may be implemented using, for example, bus bars or other types of transmission elements capable of distributing electrical power. While not shown, it will be appreciated that the power domains may include various power management components (e.g., fuses, switches, etc.) to facilitate selective distribution of power within the power domains.

Turning now to FIG. 2B, FIG. 2B shows another example of the data processing system 240 shown in FIG. 2A. In particular, FIG. 2B shows an abridged (e.g., simplified) version of the data processing system 240 with certain components visually removed for simplicity. Said another way, although not shown in FIG. 2B, the data processing system 240 of FIG. 2B still includes all of the components shown in FIG. 2A.

As shown in FIG. 2B, data processing system 240 includes a first thermal driver 290, a second thermal driver 292, an embedded controller 294, a fan 296, and a motherboard 298. Each of these components will be described below.

In embodiments, the motherboard 298 may be a circuit board that includes the processor (e.g., a main processor, main CPU) of the data processing system 240. The motherboard 298 may also include and/or be directly connected to one or more thermal sensors (e.g., on-board thermistors) installed in the data processing system 240. In embodiments, the motherboard 298 and the main processor of the data processing system 240 may be adapted from a thermal architecture that is only capable of providing passive cooling through throttling of a motherboard (namely, the main processor installed on the motherboard) of the data processing system 240.

In some embodiments, the motherboard 298 may be implemented in the form of just the main processor as a system-on-a-chip (SoC).

In embodiments, the motherboard 298 may host (e.g., through the main processor) the first thermal driver 290 (e.g., in the form of hardware, software, or a combination thereof). During a pre-boot stage (e.g., before an OS hosted on the main processor has completed booting/starting up), the first thermal driver 290 may be a driver execution environment (DXE) driver (also referred to herein as a “DXE thermal driver”). After the pre-boot stage and after the OS is operational, the first thermal driver 290 may be a high-level operating system (HLOS) driver (also referred to herein as a “HLOS thermal driver”).

Regardless of which stage (e.g., during or after pre-boot) the data processing system 240 is in, the first thermal driver 290 may be configured to retrieve a system temperature of the data processing system 240 via thermal measurements (e.g., thermal information) from various components of the data processing system including: (i) the motherboard 298 and the main processor; (ii) other SoCs installed in the data processing system 240 including GPUs of the like; (iii) the one or more thermal sensors (e.g., on-board thermistors) installed within the data processing system 240); (iv) from the basic input/output system (BIOS) of the data processing system 240; or the like. In embodiments, the first thermal driver 290 retrieves the thermal measurements directly from these components of the data processing system 240 without using platform environment control interface (PECI) tunneling through an enhanced serial peripheral interface (eSPI) interface.

In embodiments, the second thermal driver 292 may be implemented in hardware, software, or a combination of both. The second thermal driver 292 may be configured to retrieve the thermal measurements from the first thermal driver 290 and forward the thermal measurements to the embedded controller 294. In embodiments, the second thermal driver 292 is the only component withing the data processing system 240 that is capable of performing this task of providing the thermal measurements from the first thermal driver 290 to the embedded controller 294. Said another way, in embodiments, the embedded controller 294 is not capable of retrieving the thermal measurements directly from the first thermal driver 290.

During a pre-boot stage (e.g., before an OS hosted on the main processor has completed booting/starting up), the second thermal driver 292 may be a driver execution environment (DXE) driver interface. After the pre-boot stage and after the OS is operational, the second thermal driver 292 may be an advanced configuration and power interface source language (ACPI ASL) based driver.

During the pre-boot stage, the second thermal driver 292 may obtain the thermal measurements from the first thermal driver 290 using a Unified Extensible Firmware Interface (UEFI) Timer Event mechanism. After the pre-boot stage and after the OS is operational, the second thermal driver 292 may be configured to implement ACPL ASL techniques to forward the thermal measurements from the first thermal driver 290 to the embedded controller 294.

In embodiments, during the pre-boot stage, the second thermal driver 292 (as the DXE driver interface) communicates the thermal measurements to the embedded controller 294 using Multi-Channel Inter-Processor Mailbox (MBOX) I2C/I3C communication protocol via an inter-integrated circuit (I2C)/improved inter-integrated circuit (I3C) interface. The I2C/I3C interface may be implemented as an out of band (OOB) communication channel. After the pre-boot stage and after the OS is operational, the second thermal driver 292 (as the ACPI ASL based driver) communicates the thermal measurements to the embedded controller 294 using an ASL-I2C/I3C communication protocol via the I2C/I3C interface.

In embodiments, the embedded controller 294 may be the same as any of the embedded controllers discussed in FIG. 2A (e.g., an embedded controller that is part of hardware resources 250 and/or the management controller 252 of FIG. 2A). The embedded controller 294 may be configured to use the thermal measurements provided by the second thermal driver 292 to control: (i) the operations of fan 296 to actively cool the data processing system 240 by controlling a fan speed of the fan 296 using a linear fan control thermal framework (or the like) based on the thermal measurements; and/or (ii) throttling of the motherboard 298 (namely, the main processor on the motherboard 298) using the thermal measurements.

In embodiments, the fan 296 may be any type of physical (e.g., hardware type) fan that can be installed in computing devices to provide cooling (e.g., by blowing out hot air from the data processing system 240). The data processing system 240 may include any number of the fan 296.

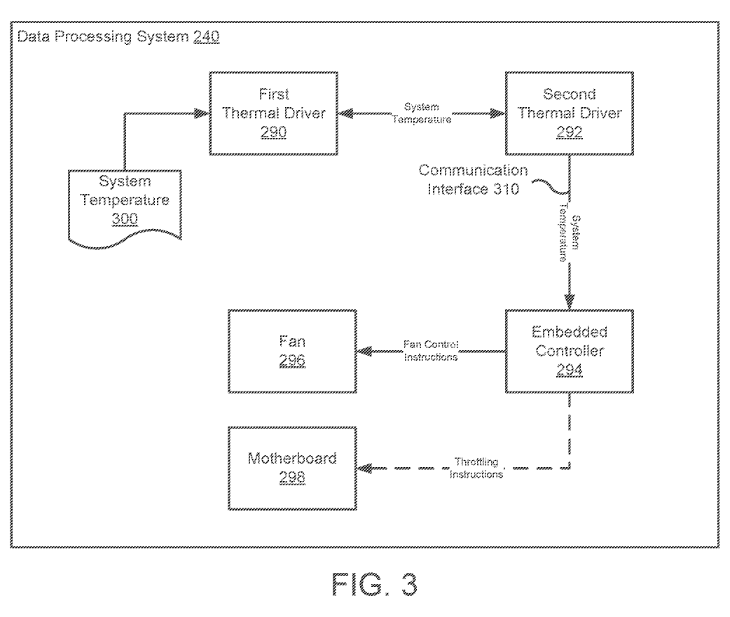

To further clarify embodiments disclosed herein, a data flow diagram in accordance with one or more embodiments disclosed herein is shown in FIG. 3. In these diagrams, flows of data and processing of data are illustrated using different sets of shapes. A first set of shapes (e.g., 300, etc.) is used to represent data structures (e.g., files, data packets, or the like), a second set of shapes (e.g., 290, 292, 294, etc.) is used to represent the components (e.g., the devices, hardware and/or software components, or the like discussed above in reference to FIGS. 1-2B) that perform one or more processes using the information included in the first set of shapes.

As shown in FIG. 3, the first thermal driver 290 (e.g., first thermal driver 290 of FIG. 2B) may obtain system temperature 300 (e.g., the system temperature of the data processing system 240 made up of the thermal measurements discussed above in reference to FIG. 2B). The system temperature 300 may be obtained directly from: (i) the motherboard 298 and the main processor; (ii) other SoCs installed in the data processing system 240 including GPUs of the like; (iii) the one or more thermal sensors (e.g., on-board thermistors) installed within the data processing system 240); (iv) from the basic input/output system (BIOS) of the data processing system 240; or the like.

The system temperature 300 may be obtained by second thermal driver 292 (e.g., via retrieval from the first thermal driver 290, via receiving the system temperature 300 from the first thermal driver 290, or the like). Once obtained by the second thermal driver 292, the system temperature is forwarded to the embedded controller 294 (by the second thermal driver 292) via communication interface 310. In embodiments, communication interface 310 may be an I2C/I3C interface created between the second thermal driver 292 and the embedded controller 294. In embodiments, the embedded controller 294 is incapable of directly communicating with the first thermal driver 290 (hosted by motherboard 298) and vice versa.

Upon receiving the system temperature 300, the embedded controller 294 may use the system temperature 300 to determine (e.g., using a linear fan control thermal framework or the like) whether to: (i) generate fan control instructions to cause a fan 296 to run and blow hot air out of the data processing system 240; or (ii) generate throttling instructions for the motherboard (namely, the main processor of the data processing system 240 installed on the motherboard 298) to perform throttling to cool down the data processing system.

In particular, in a first example of embodiments disclosed herein, assume for this first example that the data processing system 240 is in a pre-boot stage (e.g., in UEFI mode). During this UEFI mode (where the operating system has not started up yet and is not available), further assume that the system temperature 300 (e.g., Tj of the data processing system 240) has exceeded a predetermined system temperature threshold (e.g., the data processing system 240 is starting to overheat in UEFI mode). The system temperature 300 may be communicated to the embedded controller 294 by a DXE driver interface (e.g., second thermal driver 292) over communication interface 310 using an MBOX I2C/I3C communication protocol. The DXE driver interface (e.g., second thermal driver 292) may have obtained the system temperature 300 from a DXE driver (e.g., first thermal driver 292) using a UEFI Timer Event mechanism. Upon receiving the system temperature 300 and determining (e.g., using a linear fan control thermal framework or the like) that the system temperature 300 has exceeded a predetermined system temperature threshold, the embedded controller 294 may generate fan control instructions to cause the fan 296 to actively cool the data processing system 240 (instead of passively cooling by throttling motherboard 298).

As a result, in this first example, the data processing system 240 may advantageously be cooled using active cooling techniques during a pre-boot stage and utilizing components (e.g., the motherboard, on-board thermistors, and the like) from a thermal architecture that is only capable of providing passive cooling techniques.

As a second example of embodiments disclosed herein, assume for this example all of the same conditions as in the first example. Further assume now that the active cooling provided by the fan 296 is not enough to cool the data processing system 240 to drop below the predetermined system temperature threshold. While still in the pre-boot state (e.g., UEFI mode), the embedded controller 294 may generate throttling instructions to cause the throttling of the main processor of the data processing system 240 to further cool the data processing system 240 alongside the fan cooling.

As a third example of embodiments disclosed herein, assume now that the data processing system 240 has finished booting up and an OS of the data processing system 240 is operational. Assume again that the system temperature 300 has now exceeded the predetermined system temperature threshold. The system temperature 300 is communicated by the HLOS thermal driver (e.g., the first thermal driver 290) to the embedded controller 294 through using ACPI ASL (e.g., via the second thermal driver 292) over communication interface 310 (e.g., using an ASL-I2C/I3C communication protocol via an I2C/I3C interface). Similar to the first and second examples, the embedded controller 294 will use the system temperature received through the second thermal driver 292 to cool down data processing system 240.

As a result, in all three examples, the data processing system 240 is now provided with active cooling capabilities (e.g., via the embedded controller 294 and the fan 296) in both pre-boot and post boot stages even though the data processing system 240 is installed with components (e.g., the motherboard 298 or the like) from a thermal architecture that is only capable of providing passive cooling using throttling and that is not initially designed to be compatible with the embedded controller 294 and fan 296.

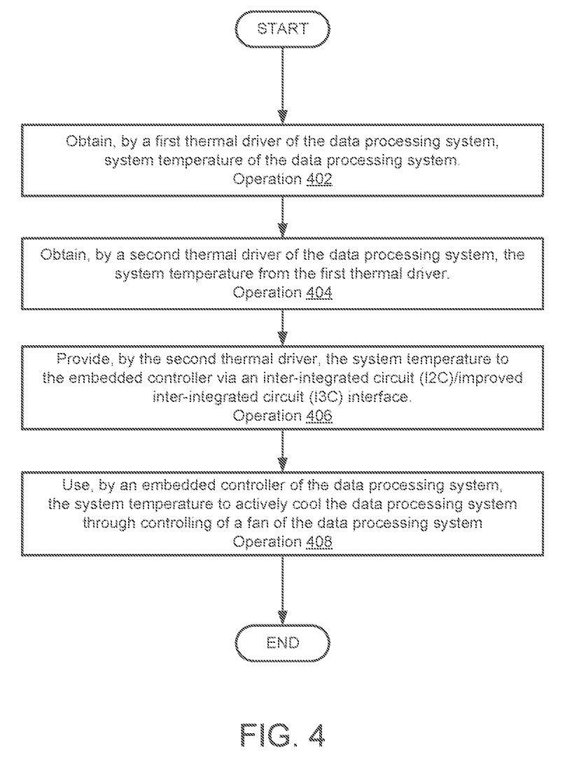

As discussed above, the components of FIGS. 1-2B may perform various methods for managing a boot up process of a data processing system. FIG. 4 illustrates an example method that may be performed by the components of FIGS. 1-2B. For example, any of the data processing system 102, and/or the other devices 103 shown in FIG. 1 may include components (e.g., shown in FIGS. 2A-2B) that are capable of performing all or a portion of the method of FIG. 4. In the diagram discussed below and shown in FIG. 4, any of the operations may be repeated, performed in different orders, and/or performed in parallel with or in a partially overlapping in time manner with other operations.

In Operation 402 of FIG. 4, and as discussed above in reference to FIGS. 2B-3, a first thermal driver (e.g., 290, FIGS. 2B and 3) of a data processing system may obtain system temperature of the data processing system.

In embodiments, the first thermal driver (e.g., hosted by a motherboard of the data processing system) may be a component from a thermal architecture that is only capable of providing passive cooling through throttling of the motherboard. In embodiments, the first thermal driver being incapable of communicating with an embedded controller of the data processing system that provides active cooling for the data processing system using one or more fans of the data processing system.

In Operation 404, and as discussed above in reference to FIGS. 2B-3, a second thermal driver (e.g., 292, FIGS. 2B and 3) of the data processing system may obtain system temperature from the first thermal driver.

In Operation 406, and as discussed above in reference to FIGS. 2B-3, the second thermal driver may provide the system temperature to the embedded controller via an I2C/I3C interface.

In embodiments, when the method is performed during a startup process (e.g., during a pre-boot stage) of the data processing system before an operating system (OS) has completed booting up, the first thermal driver is a first Driver Execution Environment (DXE) driver that obtains the system temperature directly from a motherboard installed within the data processing system, and the second thermal driver is a second DXE driver that obtains the system temperature from the first DXE driver using a Unified Extensible Firmware Interface (UEFI) Timer Event mechanism. In embodiments, the second DXE driver obtains the system temperature from the first DXE driver by retrieving the system temperature from the first DXE driver using the UEFI Timer Event mechanism, and the second DXE driver provides the system temperature to the embedded controller using a Multi-Channel Inter-Processor Mailbox (MBOX) I2C/I3C communication protocol.

In embodiments, when the method is performed after completion of a startup process (e.g., after completion of the pre-boot stage) of the data processing system when the OS of the data processing system is running, the first thermal driver is high-level operating system (HLOS) thermal driver that obtains the system temperature directly from the motherboard, and the second thermal driver is an Advanced Configuration and Power Interface Source Language (ASL) based driver. In embodiments, the second thermal driver provides the system temperature to the embedded controller using an ASL-I2C/I3C communication protocol.

In Operation 408, and as discussed above in reference to FIGS. 2B-3, the system temperature may be used by the embedded controller to actively cool the data processing system through controlling of a fan of the data processing system and/or through throttling a main processor (installed on the motherboard) of the data processing system.

In embodiments, the embedded controller is incapable of obtaining the system temperature without aid from the second thermal driver. Said another way, the embedded controller is incapable of directly obtaining the system temperature from the first thermal driver without going through (e.g., using) the second thermal driver.

The method may end following operation 408.

Any of the components illustrated in FIGS. 1-4 may be implemented with one or more computing devices. Turning to FIG. 5, a block diagram illustrating an example of a data processing system (e.g., a computing device) in accordance with an embodiment is shown. For example, system 500 may represent any of data processing systems described above performing any of the processes or methods described above. System 500 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 500 is intended to show a high-level view of many components of the computer system. However, it is to be understood that additional components may be present in certain implementations and furthermore, different arrangement of the components shown may occur in other implementations.

System 500 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 500 includes processor 501, memory 503, and devices 505-508 via a bus or an interconnect 510. Processor 501 may represent a single processor or multiple processors with a single processor core or multiple processor cores included therein. Processor 501 may represent one or more general-purpose processors such as a microprocessor, a central processing unit (CPU), or the like.

More particularly, processor 501 may be a complex instruction set computing (CISC) microprocessor, reduced instruction set computing (RISC) microprocessor, very long instruction word (VLIW) microprocessor, or processor implementing other instruction sets, or processors implementing a combination of instruction sets.

Processor 501 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 501, which may be a low power multi-core processor socket such as an ultra-low voltage processor, may act as a main processing unit and central hub for communication with the various components of the system. Such processor can be implemented as a system on chip (SoC). Processor 501 is configured to execute instructions for performing the operations discussed herein. System 500 may further include a graphics interface that communicates with optional graphics subsystem 504, which may include a display controller, a graphics processor, and/or a display device.

Processor 501 may communicate with memory 503, which in one embodiment can be implemented via multiple memory devices to provide for a given amount of system memory. Memory 503 may include one or more volatile storage (or memory) devices such as random-access memory (RAM), dynamic RAM (DRAM), synchronous DRAM (SDRAM), static RAM (SRAM), or other types of storage devices. Memory 503 may store information including sequences of instructions that are executed by processor 501, or any other device.

For example, executable code and/or data of a variety of operating systems, device drivers, firmware (e.g., input output basic system or BIOS), and/or applications can be loaded in memory 503 and executed by processor 501. An operating system can be any kind of operating systems, such as, for example, Windows^{®} operating system from Microsoft^{®}, Mac OS^{®}/iOS^{®} from Apple, Android^{®} from Google^{®}, Linux^{®}, Unix^{®}, or other real-time or embedded operating systems such as VxWorks.

System 500 may further include IO devices such as devices (e.g., 505, 506, 507, 508) including network interface device(s) 505, optional input device(s) 506, and other optional IO device(s) 507. Network interface device(s) 505 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 506 may include a mouse, a touch pad, a touch sensitive screen (which may be integrated with a display device of optional graphics subsystem 504), a pointer device such as a stylus, and/or a keyboard (e.g., physical keyboard or a virtual keyboard displayed as part of a touch sensitive screen). For example, input device(s) 506 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 507 may include an audio device. An audio device may include a speaker and/or a microphone to facilitate voice-enabled functions, such as voice recognition, voice replication, digital recording, and/or telephony functions. Other IO devices 507 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 507 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 510 via a sensor hub (not shown), while other devices such as a keyboard or thermal sensor may be controlled by an embedded controller (not shown), dependent upon the specific configuration or design of system 500.

To provide for persistent storage of information such as data, applications, one or more operating systems and so forth, a mass storage (not shown) may also couple to processor 501. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 501, e.g., via a serial peripheral interface (SPI). This flash device may provide for non-volatile storage of system software, including a basic input/output software (BIOS) as well as other firmware of the system.

Storage device 508 may include computer-readable storage medium 509 (also known as a machine-readable storage medium or a computer-readable medium) on which is stored one or more sets of instructions or software (e.g., processing module, unit, and/or processing module/unit/logic 528) embodying any one or more of the methodologies or functions described herein. Processing module/unit/logic 528 may represent any of the components described above. Processing module/unit/logic 528 may also reside, completely or at least partially, within memory 503 and/or within processor 501 during execution thereof by system 500, memory 503 and processor 501 also constituting machine-accessible storage media. Processing module/unit/logic 528 may further be transmitted or received over a network via network interface device(s) 505.

Computer-readable storage medium 509 may also be used to store some software functionalities described above persistently. While computer-readable storage medium 509 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 528, components and other features described herein can be implemented as discrete hardware components or integrated in the functionality of hardware components such as ASICS, FPGAs, DSPs, or similar devices. In addition, processing module/unit/logic 528 can be implemented as firmware or functional circuitry within hardware devices. Further, processing module/unit/logic 528 can be implemented in any combination hardware devices and software components.

Note that while system 500 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components, or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system’s registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A method for providing active cooling using a fan controlled by an embedded controller in a data processing system having components from a thermal architecture that is only capable of providing passive cooling through throttling of a motherboard of the data processing system, the method comprising:
obtaining, by a first thermal driver of the data processing system, system temperature of the data processing system, the first thermal driver being incapable of communicating with the embedded controller;
obtaining, by a second thermal driver of the data processing system, the system temperature from the first thermal driver;
providing, by the second thermal driver, the system temperature to the embedded controller via an inter-integrated circuit (I2C)/improved inter-integrated circuit (I3C) interface; and
providing, by the embedded controller, active cooling for the data processing system by controlling the fan based on the system temperature, the embedded controller being incapable of obtaining the system temperature without aid from the second thermal driver.

2. The method of claim 1, wherein when the method is performed during a startup process of the data processing system before an operating system (OS) has completed booting up, the first thermal driver is a first Driver Execution Environment (DXE) driver that obtains the system temperature directly from a motherboard installed within the data processing system, and the second thermal driver is a second DXE driver that obtains the system temperature from the first DXE driver using a Unified Extensible Firmware Interface (UEFI) Timer Event mechanism.

3. The method of claim 2, wherein the second DXE driver obtains the system temperature from the first DXE driver by retrieving the system temperature from the first DXE driver using the UEFI Timer Event mechanism.

4. The method of claim 3, wherein the second DXE driver provides the system temperature to the embedded controller using a Multi-Channel Inter-Processor Mailbox (MBOX) I2C/I3C communication protocol.

5. The method of claim 2, wherein when the method is performed after completion of a startup process of the data processing system when the OS of the data processing system is running, the first thermal driver is high-level operating system (HLOS) thermal driver that obtains the system temperature directly from the motherboard, and the second thermal driver is an Advanced Configuration and Power Interface Source Language (ASL) based driver.

6. The method of claim 5, wherein the second thermal driver provides the system temperature to the embedded controller using an ASL-I2C/I3C communication protocol.

7. The method of claim 2, further comprising:
determining, during the startup process and while the embedded controller provides the active cooling using the fan, that the system temperature is still above a predetermined threshold; and
causing, by the embedded controller and in response to the determination, throttling of the motherboard to also provide the passive cooling in addition to providing the active cooling using the fan.

8. The method of claim 1, wherein the thermal architecture is based on a passive cooling thermal architecture of a computing device without a capacity to include the fan and the embedded controller, and the motherboard is one of the components of the thermal architecture.

9. A non-transitory machine-readable medium having instructions stored therein, which when executed by a processor, cause the processor to perform operations for providing active cooling using a fan controlled by an embedded controller in a data processing system having components from a thermal architecture that is only capable of providing passive cooling through throttling of a motherboard of the data processing system, the operations comprising:
obtaining, by a first thermal driver of the data processing system, system temperature of the data processing system, the first thermal driver being incapable of communicating with the embedded controller; obtaining, by a second thermal driver of the data processing system, the system temperature from the first thermal driver;
providing, by the second thermal driver, the system temperature to the embedded controller via an inter-integrated circuit (I2C)/improved inter-integrated circuit (I3C) interface; and
providing, by the embedded controller, active cooling for the data processing system by controlling the fan based on the system temperature, the embedded controller being incapable of obtaining the system temperature without aid from the second thermal driver.

10. The non-transitory machine-readable medium of claim 9, wherein when the operations are performed during a startup process of the data processing system before an operating system (OS) has completed booting up, the first thermal driver is a first Driver Execution Environment (DXE) driver that obtains the system temperature directly from a motherboard installed within the data processing system, and the second thermal driver is a second DXE driver that obtains the system temperature from the first DXE driver using a Unified Extensible Firmware Interface (UEFI) Timer Event mechanism.

11. The non-transitory machine-readable medium of claim 10, wherein the second DXE driver obtains the system temperature from the first DXE driver by retrieving the system temperature from the first DXE driver using the UEFI Timer Event mechanism.

12. The non-transitory machine-readable medium of claim 11, wherein the second DXE driver provides the system temperature to the embedded controller using a Multi-Channel Inter-Processor Mailbox (MBOX) I2C/I3C communication protocol.

13. The non-transitory machine-readable medium of claim 10, wherein when the operations are performed after completion of a startup process of the data processing system when the OS of the data processing system is running, the first thermal driver is high-level operating system (HLOS) thermal driver that obtains the system temperature directly from the motherboard, and the second thermal driver is an Advanced Configuration and Power Interface Source Language (ASL) based driver.

14. The non-transitory machine-readable medium of claim 13, wherein the second thermal driver provides the system temperature to the embedded controller using an ASL-I2C/I3C communication protocol.

15. The non-transitory machine-readable medium of claim 10, wherein the operations further comprise:
determining, during the startup process and while the embedded controller provides the active cooling using the fan, that the system temperature is still above a predetermined threshold; and
causing, by the embedded controller and in response to the determination, throttling of the motherboard to also provide the passive cooling in addition to providing the active cooling using the fan.

16. The non-transitory machine-readable medium of claim 9, wherein the thermal architecture is based on a passive cooling thermal architecture of a computing device without a capacity to include the fan and the embedded controller, and the motherboard is one of the components of the thermal architecture.

17. A data processing system having components from a thermal architecture that is only capable of providing passive cooling through throttling of a motherboard of the data processing system comprising:
a fan;
an embedded controller configured to provide active cooling for the data processing system using the fan;
a processor installed on the motherboard; and
a memory coupled to the processor, the memory storing instructions that, when executed by the data processing system, causes the data processing system to provide the active cooling using the fan and the embedded controller, the operations comprising:
obtaining, by a first thermal driver of the data processing system, system temperature of the data processing system, the first thermal driver being incapable of communicating with the embedded controller;
obtaining, by a second thermal driver of the data processing system, the system temperature from the first thermal driver; providing, by the second thermal driver, the system temperature to the embedded controller via an inter-integrated circuit (I2C)/improved inter-integrated circuit (I3C) interface; and providing, by the embedded controller, active cooling for the data processing system by controlling the fan based on the system temperature, the embedded controller being incapable of obtaining the system temperature without aid from the second thermal driver.

18. The data processing system of claim 17, wherein when the operations are performed during a startup process of the data processing system before an operating system (OS) has completed booting up, the first thermal driver is a first Driver Execution Environment (DXE) driver that obtains the system temperature directly from a motherboard installed within the data processing system, and the second thermal driver is a second DXE driver that obtains the system temperature from the first DXE driver using a Unified Extensible Firmware Interface (UEFI) Timer Event mechanism.

19. The data processing system of claim 18, wherein the second DXE driver obtains the system temperature from the first DXE driver by retrieving the system temperature from the first DXE driver using the UEFI Timer Event mechanism.

20. The data processing system of claim 18, wherein when the operations are performed after completion of a startup process of the data processing system when the OS of the data processing system is running, the first thermal driver is high-level operating system (HLOS) thermal driver that obtains the system temperature directly from the motherboard, and the second thermal driver is an Advanced Configuration and Power Interface Source Language (ASL) based driver.
